(19) United States
(12) Patent Application Publication
(10) Pub. No.: US 2015/0333476 A1
(43) Pub. Date: Nov. 19, 2015

(54) SOLDERABLE PAD FABRICATION FOR MICROELECTRONIC COMPONENTS

(71) Applicant: Seagate Technology LLC, Cupertino, CA (US)

(72) Inventors: Lijuan Zhong, Eden Prairie, MN (US); Joseph Michael Stephan, Eden Prairie, MN (US); The Ngoc Nguyen, Lakeville, MN (US); Carl Kristian Lunde, Lakeville, MN (US)

(21) Appl. No.: 14/810,795

(22) Filed: Jul. 28, 2015

Related U.S. Application Data
(62) Division of application No. 13/783,901, filed on Mar. 4, 2013, now abandoned.
(60) Provisional application No. 61/637,255, filed on Apr. 23, 2012.

(51) Int. Cl. H01S 5/022; G11B 5/127; H01S 5/02

(52) U.S. Cl. CPC H01S 5/02272; H01S 5/02268; H01S 5/0201; G11B 5/1272

(57) ABSTRACT

Two microelectronic components can be attached by flowing solder between solderable pads patterned on interfacing surfaces. According to one implementation, the microelectronic components can include the solderable pads patterned onto first respective surfaces and other surface features patterned onto second respective surfaces. In another implementation, the solderable pads can include an adhesion layer, a diffusion barrier layer, and a surface oxidation layer.

### CROSS-REFERENCE TO RELATED APPLICATION

This application is a divisional application of U.S. application Ser. No. 13/783,901 filed Mar. 4, 2013, which claims priority to U.S. provisional application 61/637,255 filed Apr. 23, 2012, the entire disclosures of which are incorporated herein by reference for all purposes.

### BACKGROUND

Microelectronic components may be bound together by adhesives. However, adhesive joints are sensitive to environmental conditions, such as heat, solvent, or moisture, which may cause joint alignment between components to degrade during curing and over time.

### SUMMARY

In one implementation, a method includes patterning features on a first surface of a first microelectronic component; rotating the first microelectronic component, patterning a solderable pad on a second surface of the first microelectronic component, and patterning a layer of solder on the solderable pad.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. These and various other features and advantages will be apparent from a reading of the following Detailed Description.

### BRIEF DESCRIPTIONS OF THE DRAWINGS

FIG. 1 illustrates a plan view of an example disc drive assembly including a transducer on a distal end of an actuator arm positioned over a media disc.

FIG. 2 illustrates patterning and slicing steps in fabricating solderable pads for microelectronic components.

FIG. 3 illustrates a rotation step in fabricating solderable pads for microelectronic components.

FIG. 4 illustrates a mounting step in fabricating solderable pads for microelectronic components.

FIG. 5 illustrates an isometric view of a microelectronic component with a layer of resist applied to one surface.

FIG. 6 illustrates an x-z cross section of an example microelectronic component with a patterned photoresist formed thereon.

FIG. 7 illustrates an x-z cross section of an example microelectronic component with a patterned photoresist, a solderable pad, and a layer of solder formed thereon.

FIG. 8 illustrates an x-z cross section of another example microelectronic component with a solderable pad and solder layer formed thereon.

FIG. 9 illustrates an isometric view of a submount with a solderable pad and solder layer patterned on a first surface and additional surface features patterned onto a second surface.

FIG. 10 illustrates an isometric view of a slider with a solderable pad patterned on a surface.

FIG. 11 illustrates a side profile of a submount and a slider positioned for an alignment and attachment step.

FIG. 12 illustrates an isometric view of a HAMR head including a submount bonded to a slider by a solder joint between solderable pads on interfacing surfaces of the submount and the slider.

FIG. 13 is a flow-chart of example operations for fabricating solderable pads on a microelectronic component.

### DETAILED DESCRIPTIONS

Heat assisted magnetic recording, optical assisted recording and thermal assisted recording (collectively hereinafter HAMR) generally refer to the concept of locally heating a recording medium to reduce the coercivity of the recording medium so that an applied magnetic write field can more easily induce magnetization of the recording medium during a temporary magnetic softening of the recording medium caused by the local heating. To perform HAMR, heat or a light source can be applied to a magnetic medium and confined to a bit location where a write operation is taking place. For example, a laser beam can be propagated through a waveguide and focused by a focusing element such as a planar solid immersion mirror into a near-field transducer.

However, HAMR devices utilize an attachment between the waveguide and the laser that achieves a precision alignment. During use, the attachment mechanism may be subjected to intense heat generated by the laser. Adhesives are not ideal attachment mechanisms for components in HAMR devices because adhesives are vulnerable to environmental forces during device fabrication and operation, such as heat, which can cause the adhesive joint to deform or weaken over time. Solder is not commonly used to attach components in HAMR devices because, among other reasons, the surfaces to be joined via solder are generally not the primary surfaces where microstructures are patterned. Additionally, traditional solder application methods, such as solder jet, solder paste print, create tall solder balls or thick solder pads, which may interfere with or prevent precision alignment between the components, such as the slider and the laser submount assembly.

Also some of the methods and techniques disclosed herein may be described with specific reference to a slider and/or a submount. Other microelectronic component technologies may also be suitable for practicing one or more of the disclosed implementations.

The disclosed technology provides for the fabrication of solderable pads on microelectronic components. As used herein, the term “microelectronic” refers to small electronics made of semi-conductor materials that are typically measured on the micrometer-scale or smaller. This class of electronics includes micro electro-optical components such as those common in HAMR devices.

According to one or more implementations disclosed herein, a joint with a high degree of mechanical strength can be created by flowing a thin film layer of solder between solderable pads on interfacing surfaces of two microelectronic components. The thin film layer of solder may also provide for a tight alignment between the components with micron or submicron precision. The surface on which a solderable pad is formed may be different from a primary surface on the same component (e.g., the submount or the slider) where additional patterning is performed. The microelectronic component may be rotated as appropriate for patterning on more than one surface. As used herein, the term “patterning” shall refer to the creation of one or more microstructures created by lithographic processes and techniques, including but not limited to photolithography and/or nano imprint lithography.

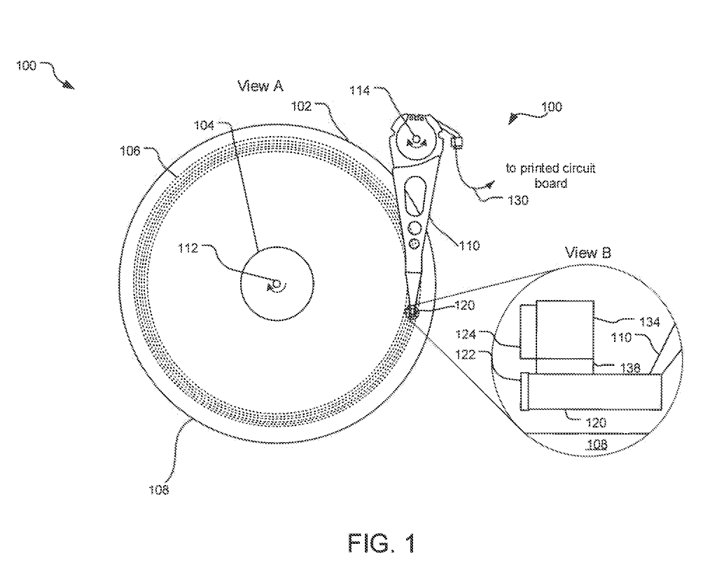

FIG. 1 illustrates a plan view of an example disc drive assembly 100 including a slider 120 (an example microelectronic component) on a distal end of an actuator arm 110 positioned over a media disc 108. Referring specifically to View A, the media 108 includes an outer diameter 102 and inner diameter 104 between which are a number of data tracks 106 illustrated by circular dotted lines. A rotary voice coil motor that rotates about an actuator axis of rotation 114 is typically used to position the slider 120 on a data track 106 on the media 108 while a spindle motor that rotates about disc axis of rotation 112 is used to rotate the media.

Information may be written to and read from the data tracks 106 on the media 108 through the use of the actuator arm 110. The actuator arm 110 rotates about the actuator axis of rotation 114 during a seek operation to locate a desired data track on the media 108. The actuator arm 110 extends toward the media 108, and at the distal end of the actuator arm 110 is the slider 120, which flies in close proximity above the media 108 while reading and writing data to the media 108. In other implementations, there is more than one slider 120, actuator arm 110, and/or media 108 in the disc drive assembly 100.

A flex cable 130 provides electrical connection paths for the slider 120 while allowing pivotal movement of the actuator arm 110 during operation. The flex cable 130 also provides power for an on-slider laser light source.

The slider 120 shown in View B of FIG. 1 is attached to a laser submount assembly (i.e., the “submount”)(another example microelectronic component) having a laser light source 124 (e.g., a laser diode) or other light source (e.g., a light emitting diode (LED)). The submount 134 is joined to the slider 120 at a solder joint 138. In one implementation, the solder joint 138 was created by flowing solder between two solderable pads fabricated on interfacing surfaces of the slider 120 and of the submount 134, respectively. The solderable pads (not shown) may contain multiple thin film layers with different functions such as an adhesion layer, a diffusion barrier, and a surface oxidation barrier. In at least one implementation, the solderable pads are patterned onto a surface of one of the microelectronic components (e.g., the slider 120 and submount 134) that is different from a primary surface where microstructures are patterned using lithography tooling and techniques. As used herein, the term “thin film” shall refer to a layer having a thickness that is less than or substantially equal to about 10 microns.

The slider 120 includes a number of microstructures on a media-facing side of the slider 120, some or all of which may be created using lithographic patterning techniques. For instance, the slider 120 includes a writer section (not shown), that has a main write pole magnetically coupled to a return or opposing pole by a yoke or pedestal. A magnetization coil surrounds the yoke or pedestal to induct magnetic write pulses in the write pole. In other implementations, the slider 120 may be constructed without a yoke or return pole. The slider 120 also includes one or more read sensors (not shown) for reading data off from media 108.

The laser light source 124 is mounted to the submount 134, and attached to the slider 120. Light from the laser light source 124 is directed through a waveguide 122 on the trailing edge of the slider 120. Using the waveguide, the light is then redirected and/or focused on a point on the media 108 in close proximity to the write pole on the slider 120. A near-field transducer (NFT) may also be mounted on the slider 120 to further concentrate the light on the point on the media 108. In another implementation, one or more of the laser light source 124, the waveguide 122, mirrors (not shown), and/or NFTs (not shown) are mounted on an area of the slider 120 other than the trailing surface.

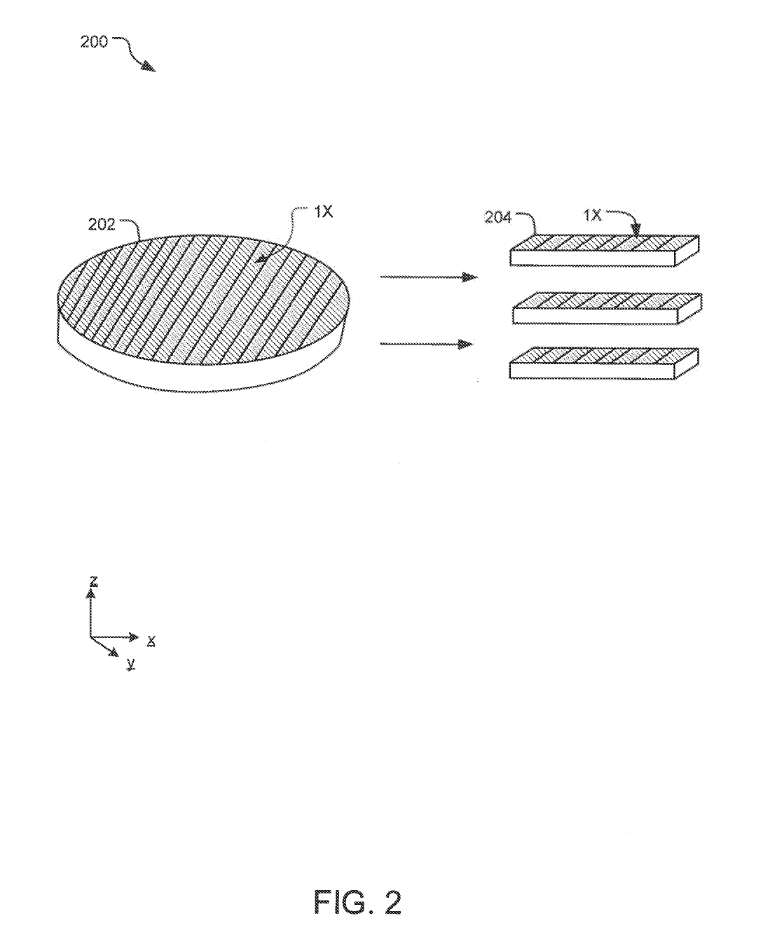

FIG. 2 illustrates a patterning and slicing step 200 in fabricating a solderable pad for a microelectronic component. In the patterning and slicing step 200, features are patterned onto a first surface (i.e., the surface 1X) of a semiconductor wafer 202. This patterning may be performed, for example, using photolithographic processes and/or nano-imprint lithography processes.

The features patterned on the first surface 1X of the wafer 202 may be features of a submount (e.g., interconnect traces, metal test pads, etc.), features of a slider (e.g., features of an advanced air-bearing surface (the AAB) of the slider), etc. After this patterning is completed, the wafer is sliced into rows or bars 204 by a slicing process (as illustrated in FIG. 2).

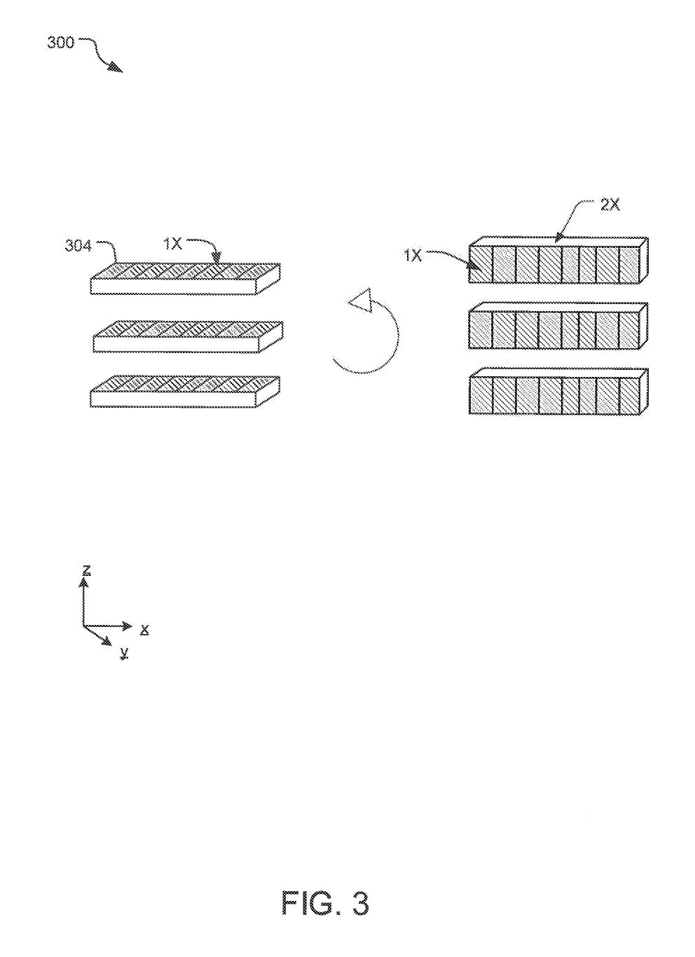

FIG. 3 illustrates a rotation step 300 in fabricating solderable pads for microelectronic components. A semiconductor wafer (not shown) with features patterned onto a first surface 1X has been sliced into rows or bars 304. At the rotation step 300, the bars 304 are rotated so that a second surface (i.e., a surface 2X) assumes the place of the surface 1X. After this rotation step 300, the second surface 2X faces patterning machinery, such as an e-beam evaporator, and is in proper position to be patterned via one or more subsequent patterning processes.

In one implementation, the bars 304 are rotated about 90 degrees from an original position at which the first surface 1X was patterned so that the second surface 2X is adjacent to, and shares an edge with, the first surface 1X.

In another implementation, the bars are rotated about 180 degrees from an original position at which the first surface 1X was patterned. For example, the second surface 2X may correspond to the back side of the one or more sliders (i.e., the side facing away from the air bearing surface of a media disc when the sliders are in use), and the first surface 1X may include surface features of the AAB (such as a read element, write element, etc.). In this implementation, the second surface 2X may not share an edge with the first surface 1X.

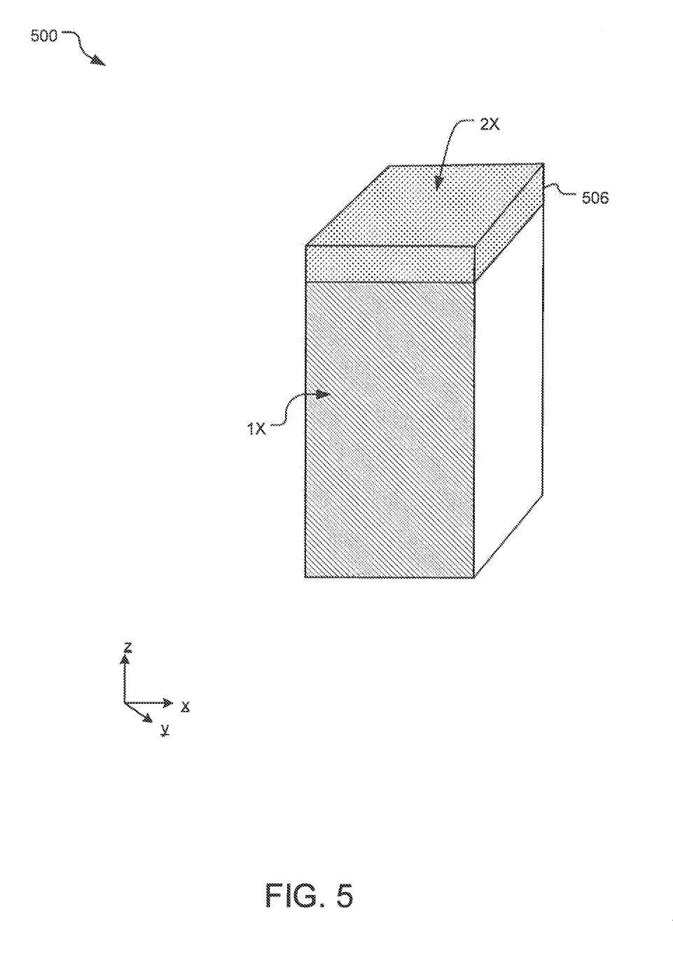

In yet another implementation, the first surface 1X may include a solderable pad such as that described with respect to FIGS. 5-8 below. The rotation step 300 rotates the microelectronic component to position the second surface 2X for subsequent patterning. After the rotation step 300, the second surface 2X may be lapped and polished in preparation for one or more subsequent patterning processes.

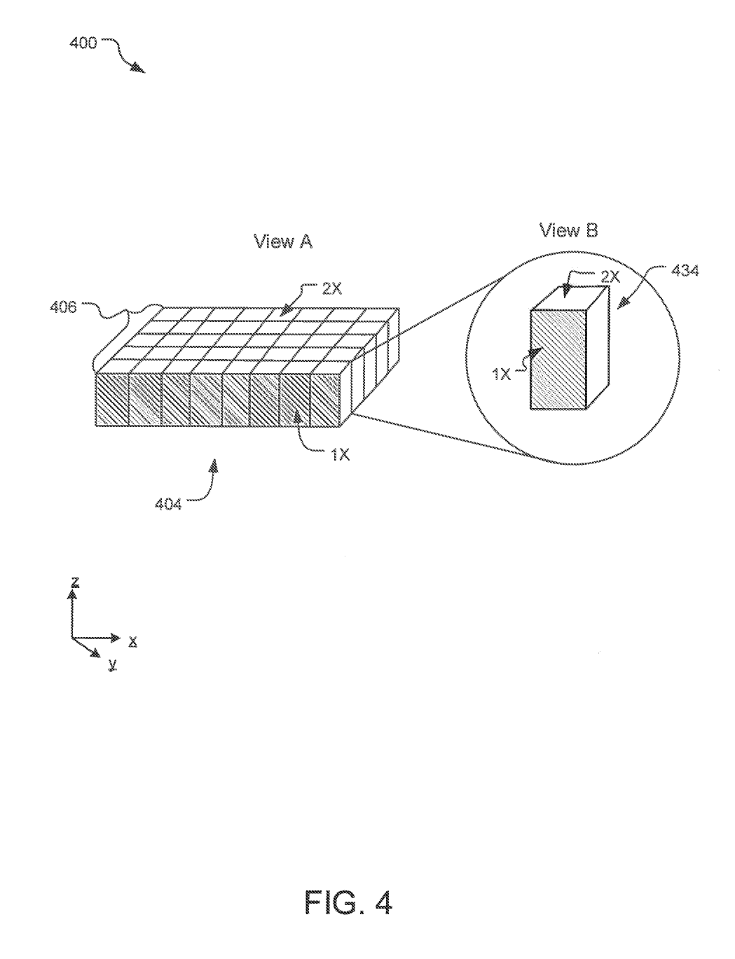

FIG. 4 illustrates a mounting step 400 in fabricating solderable pads for microelectronic components. View A of FIG. 4 shows a block 404 formed by multiple mounted bars 406 of a sliced semiconductor wafer. The bars 406 have been patterned on a first surface 1X, rotated, and mounted together as block 404 with a second surface 2X facing patterning machinery. The semiconductor bars 406 are mounted such that the second surface 2X is positioned for subsequent patterning, such as to receive, via a deposition process, one or more thin film layers. When mounting the bars 406 with the second surface 2X facing patterning machinery, the multi-bar surface may be aligned according to bar-to-bar alignment and planarity specifications that allow either liquid resist or dry film resist to be used for photolithographic patterning.

In one implementation, the bars satisfy such bar-to-bar specifications if the top surfaces of the bars are substantially aligned to within about +/−5 microns of one another, and the end surfaces of the bars (i.e., surfaces perpendicular to the top surface) are substantially aligned to within about +/−5 microns. In another implementation, the bars satisfy such planarity specifications if the variation in surface topography across the bars is less than 20 microns. In at least one implementation, special tooling and/or bar assembly processes are utilized to mount the bars 404 according to these specifications.

View B of FIG. 4 shows a microelectronic component 434 that is one of several microelectronic components in a bar 406 mounted within the block of bars 404. The microelectronic component 434 may be a submount or a slider for use in a HAMR device.

FIG. 5-8 illustrate additional example operations for fabricating a solderable pad on a surface of a microelectronic component. In at least one implementation, the operations described with respect to FIGS. 5-8 are performed on both of two microelectronic components prior to attachment of the microelectronic components to one another by a solder joint. These example operations may be performed on a microelectronic component (e.g., a slider or a submount) when it is part of a bar (e.g., a bar 406) mounted in a configuration the same or similar to that shown and described with respect to view A of FIG. 4. However, in at least one implementation, the operations of FIGS. 5-8 are performed before the wafer is sliced into bars. For example, the solderable pads may be formed on a first surface of a semiconductor wafer before the wafer is sliced and rotated (as illustrated in FIGS. 2-3).

FIG. 5 illustrates an isometric view of a microelectronic component 500 (e.g., a slider or a submount for use in a HAMR device) having a first surface 1X and a second surface 2X with a layer of resist 506 applied to one surface (i.e., surface 2X in this illustration, which may correspond to the surface 2X illustrated in FIGS. 3-4). The resist 506 may be a dry film resist coated onto a polyester substrate and applied to the microelectronic component by lamination. Alternatively, the resist 506 may be a layer of liquid resist applied to the microelectronic component by a standard deposition technique. Other types of resist may also be employed.

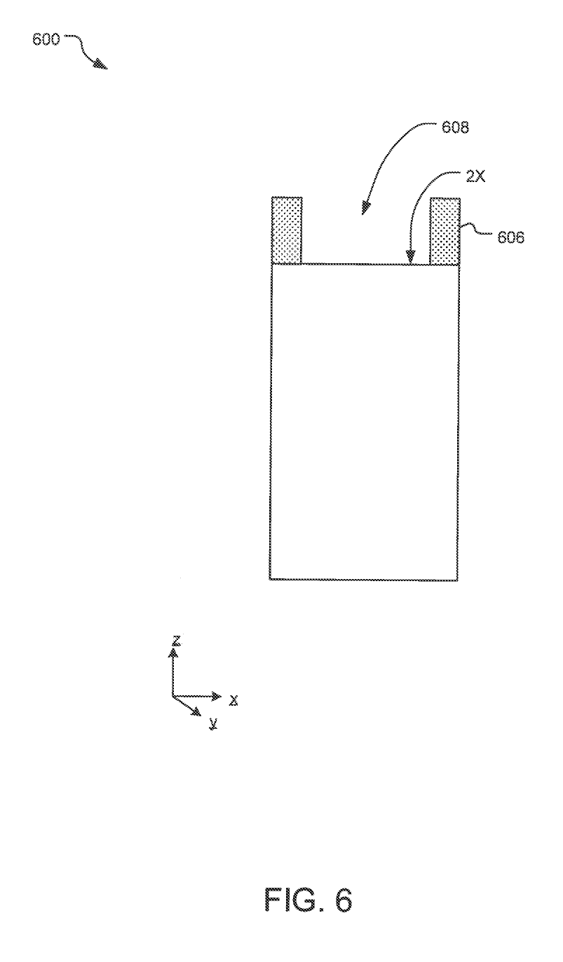

FIG. 6 illustrates an x-z cross section of an example microelectronic component 600, with a patterned photoresist 606 formed thereon. The patterned resist 606 is on a surface 2X of the microelectronic component. To create the patterned resist 606, a layer of liquid or dry film resist is applied to the surface 2X and a photomask (not shown) having a pattern corresponding to a recess 608 in the patterned resist 606 is positioned to mask portions of the surface 2X. According to one method of patterning, the unmasked portions of the resist are exposed to a high intensity light to modify the solubility of portions of the resist. After the exposure, the more soluble portions of the photoresist are removed, such as by a developer solution. The other hardened portions (i.e., the patterned resist 606) remain on the microelectronic component 600 to prevent portions of the microelectronic component from contacting one or more thin film layers that may be subsequently deposited.

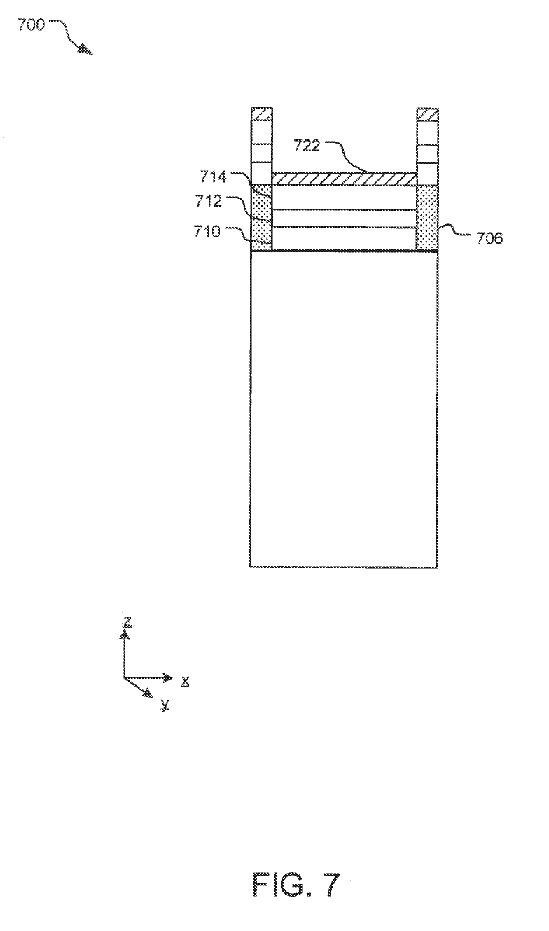

FIG. 7 illustrates an x-z cross section of an example microelectronic component 700 with a patterned photoresist 706, a solderable pad (including thin film layers 710, 712, and 714), and a layer of solder 722 formed thereon. The thin film layers 710, 712, and 714 of the solderable pad are collectively referred to herein as an under bump metallization (UBM) pad.

The trio of thin film layers 710, 712, and 714 are applied using one or more standard deposition techniques. In one implementation, the thin film layers 710, 712, and 714 are evaporated in a vacuum and condensed onto the substrate. In other implementations, the thin film layers 710, 712, and 714 are deposited using other deposition techniques, such as sputtering or plating. As a result of this deposition step, each of the thin film layers 710, 712, and 714 may be deposited substantially evenly across the microelectronic component and on top of a patterned resist 706.

The lower-most layer of the UBM pad is an adhesion layer 710 that helps the upper layers 712 and 714 adhere to the microelectronic component 700. The adhesion layer 710 can be made of a number of materials including without limitation titanium, chrome, and tantalum, as well as various alloys of such materials with other metals. In the implementation shown, the adhesion layer 710 is deposited on the microelectronic component so that it is adjacent to and in contact with a surface of the microelectronic component 700.

A diffusion barrier layer 712 is deposited on top of the adhesion layer 710 and in contact with the adhesion layer 710. The diffusion barrier layer 712 acts to protect the adhesion layer 710 from a reaction with a solder layer 722, thus preventing a reaction that might result in delamination of one or more layers of the UBM pad. In one implementation, the diffusion barrier layer 712 is nickel. However, other materials that may be used include without limitation titanium nitride, tungsten, cobalt, and alloys of such elements with other metals (e.g., NiFe).

A surface oxidation layer 714 is deposited on top of and in contact with the diffusion barrier layer 712. Because the diffusion barrier layer 712 may be prone to oxidation, the surface oxidation layer 714 insulates the diffusion barrier layer 712 and provides a wettable surface for solder application that may not be easily oxidized. In one implementation, the surface oxidation layer 714 is gold. However, other materials that may be suitable for use include, for example platinum and palladium.

Although the UBM pad in the implementation of FIG. 7 includes three layers (i.e., the adhesion layer 710, the diffusion barrier layer 712, and the surface oxidation layer 714), additional or alternative layers are contemplated. For example, between the adhesion layer 710 and diffusion barrier layer 712 there could be a functional layer included to meet additional electrical or mechanical requirements. The thickness of each of the adhesion layer 710, the diffusion barrier layer 712, and the surface oxidation layer 714 may vary; however, in one implementation the thickness of one or more the layers is substantially between about 0.01 and 1 micron.

FIG. 7 also illustrates a solder layer 722 formed on top of the surface oxidation layer 714 of the UBM pad. The solder layer 722 is deposited using a standard deposition process, which may be the same or similar to the process used to form one or more layers in the UBM pad. Because the same patterned resist 706 is left in place throughout the deposition of the UBM layers 710, 712, and 714 and the solder layer 722, precise solder to UBM pad overlay is achieved. Additionally, this process results in tight solder volume and height control.

In at least one implementation, the solder layer 722 is a thin film layer of a lead-free solder, including without limitation Ag/Sn and In/Au. The solder layer 722 can vary according to design requirements, but may have a thickness (z-direction) between about 1 micron and about 10 microns. In one example implementation, the solder layer is approximately four microns thick. This relatively small and tightly controlled solder volume satisfies the HAMR laser to slider integration needs, which may be difficult or impossible to meet using other standard solder placement techniques.

In another implementation, the solder layer 722 is applied at a later point in time, such as after the patterned resist 706 has been removed.

After the UBM is formed, the patterned resist 706 can be removed. In one implementation, the patterned resist 706 is removed by a resist-strip that chemically alters the patterned resist 706 so that it no longer adheres to the substrate. The portions of the thin film layers deposited on top of the resist 706 may also be removed by this process.

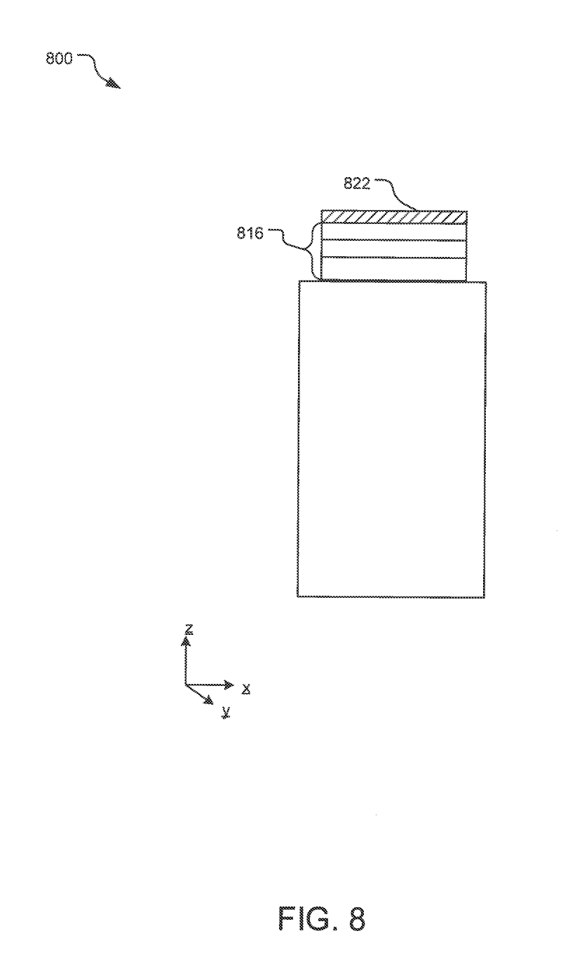

FIG. 8 illustrates an x-z cross section of another example microelectronic component 800 with a UBM pad 816 and a solder layer 822 formed thereon. The UBM pad 816 has a number of layers designed to protect the microelectronic surface and wet the solder layer 822 when heat is applied.

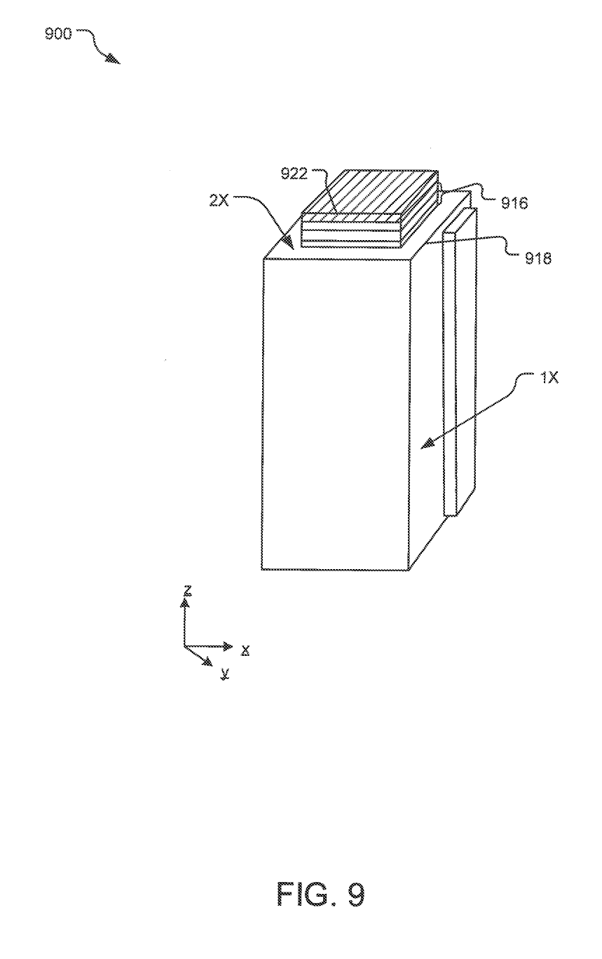

FIG. 9 illustrates an isometric view of a submount 900 with a UBM pad 916 and a solder layer 922 patterned on a surface (i.e., the surface 2X in this illustration) and additional surface features patterned onto another surface 1X. The surfaces 1X and 2X are adjacent surfaces sharing an edge 918. The UBM pad 916 may have been formed by a series of steps the same or similar to those discussed above with respect to FIGS. 5-8.

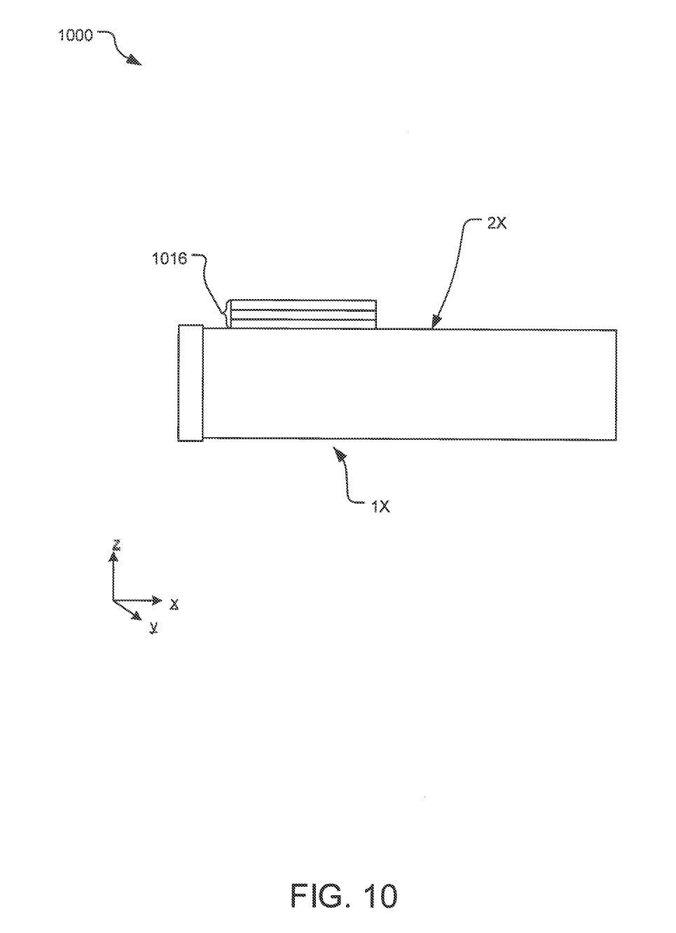

FIG. 10 illustrates an isometric view of a slider 1000 with a UBM pad 1016 patterned on a surface 2X. Additional features are patterned onto another surface 1X (i.e., the AAB surface) that is opposite the surface 2X and facing toward the air bearing surface of a media disc (not shown) when implemented in a hard drive assembly. The UBM pad 1016 may have been formed by a series of steps the same or similar to those discussed above with respect to FIGS. 5-8.

In the implementation shown, there is no solder layer on the UBM pad 1016. Rather, a solder layer may be formed on another UBM pad (not shown) on a submount (not shown) that is to be attached to the slider 1000. For example, a solder layer on a UBM pad of a submount may be brought into contact with the UBM pad 1016 on the slider 1000 just prior to or during a soldering attachment step.

In another implementation, a solder layer is formed directly onto the UBM pad 1016 of the slider 1000. Here, the solder may be applied to the UBM pad of the slider 1000 instead of or in addition to a solder layer on the UBM pad of the submount. Application of this solder may be accomplished by any standard deposition process, including those processes described above with respect to FIG. 7.

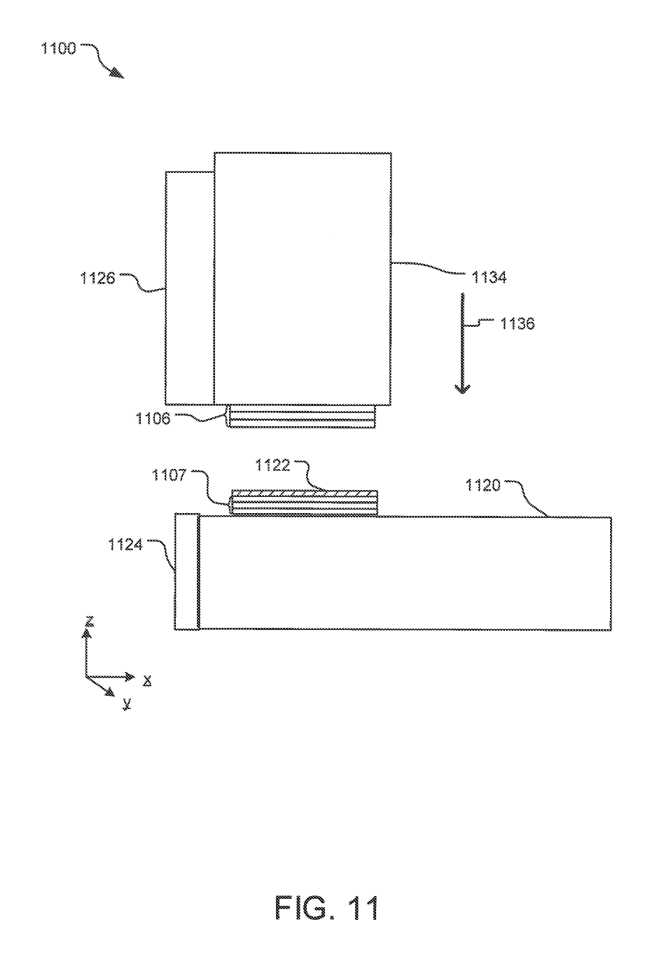

FIG. 11 illustrates a side profile of a submount 1134 and a slider 1120 positioned for an alignment and attachment step 1100. UBM pads 1106 and 1107 are formed on interfacing surfaces of the slider 1120 and the submount 1134, respectively. A solder layer 1122 is formed on the UBM pad 1107 of the slider 1120.

In other implementations, a solder layer may be formed on the UBM pad 1106 of the submount 1134 instead of or in addition to the solder layer 1122 on the UBM pad 1107 of the slider 1120.

Alignment of the submount 1134 and the slider 1120 may be active or passive. In an example active alignment, a laser 1126 on the submount 1134 is illuminated while moving above the submount 1134 in the X and Y directions to find a position of peak energy output of the laser 1126 through a waveguide 1124 on the slider 1120. When this position is found, the submount 1134 is then brought into contact with the slider 1120 by lowering the submount 1134 through the Z plane (in the direction illustrated by arrow 1136), without altering the X and Y alignment. In another implementation, the alignment involves real-time signals (e.g., electronic, optical, etc.) for feedback through either an internal sensor built in the laser 1126, submount 1134, or slider 1120, or an external sensor. Alternatively, the alignment may be a passive alignment without a real time feedback mechanism that is performed using specially-designed mechanical stops. Other alignment techniques may be employed.

Heat is applied to the solder layer 1122 just before or after the submount 1134 is brought into contact with the slider 1120. The heat flows the solder layer 1122, creating a joint that may encompass the UBM pads 1106 and 1107. In one implementation, a final alignment between the laser and submount is achieved with micron or submicron precision.

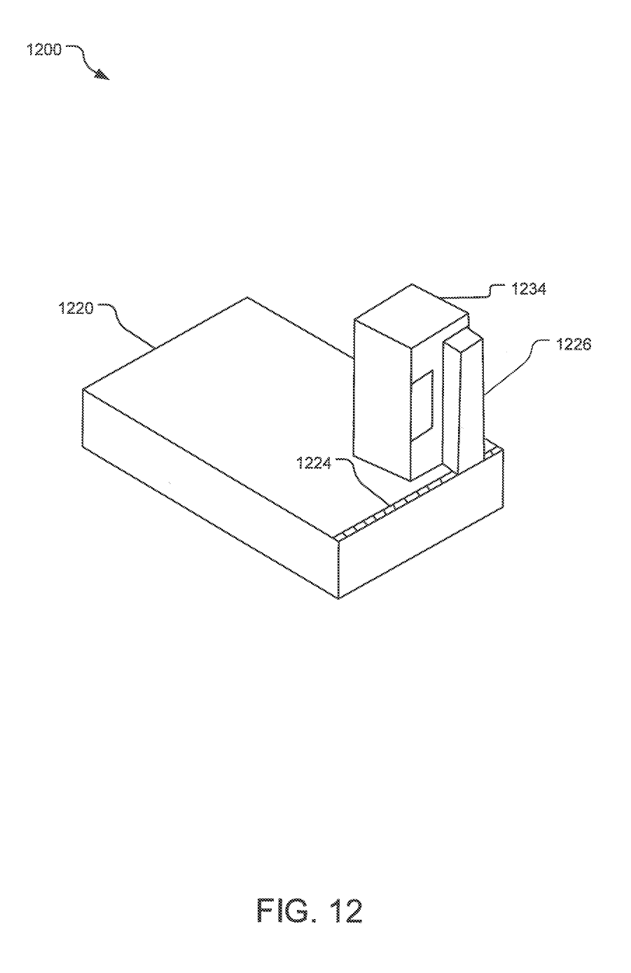

FIG. 12 illustrates an isometric view of a HAMR head 1200 including a submount 1234 with a laser 1226 bonded to a slider 1220 with a waveguide 1224 by a solder joint (not shown) between UBM pads on interfacing surfaces of the submount 1234 and the slider 1220. The joint is formed between interfacing surfaces of the slider 1220 and the submount 1234 on which one or more UBM pads were fabricated. In at least one implementation, the submount 1234 is connected to the slider 1220 through a lead-free solder connection that satisfies alignment and mechanical reliability required for HAMR light delivery.

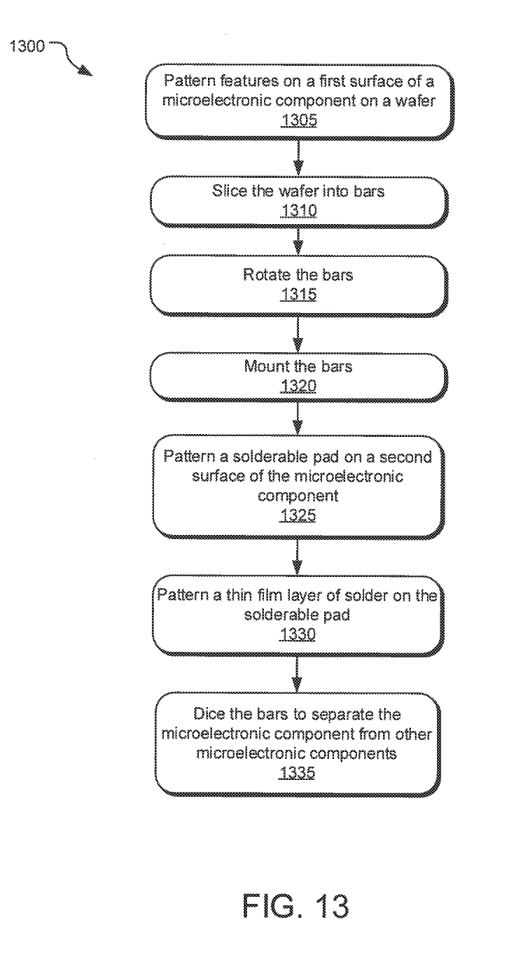

FIG. 13 is a flow-chart of example operations for a method 1300 of fabricating solderable pads on a microelectronic component.

A surface feature patterning operation 1305 patterns surface features onto a first surface of a number of microelectronic components of a semiconductor wafer. In one implementation, the surface features patterned by the surface feature patterning operation 1305 include features of the AAB surface of a slider and/or features of a laser-mounted surface of a submount. In another implementation, the surface feature patterning operation 1305 patterns one or more solderable pads and/or a solder layer onto a first surface of the microelectronic components (a process that may be performed according to operations 1325-1330, described below).

A slicing operation 1310 slices the semiconductor wafer into a series of substantially rectangular bars. In one implementation, the bars include a number of submounts for use in a HAMR device and are approximately two inches in length, 600 microns in width, and 300 microns thick. In another implementation, the bars include a number of sliders for use in a HAMR device and are approximately two inches in length, 1300 microns in width and 200 microns thick. Dimensions of the bars may vary according to design criteria.

A rotation operation 1315 rotates the bars sliced by the slicing operation 1310 to position the bars for patterning on a second surface, different from the first surface patterned by the surface feature patterning operation 1305. In one implementation, the bars include a number of submounts for use in HAMR devices, and the bars are rotated about 90 degrees from an original position at which the surface features were patterned during the surface feature patterning operation 1305. In another implementation, the bars include a number of sliders for use in HAMR devices, and the bars are rotated about 180 degrees from an original position at which the surface features were patterned during the surface feature patterning operation 1305. After the rotation operation 1315, a second surface (different from the patterned surface) of the mounted bars may be lapped and polished.

A mounting operation 1320 mounts the bars together in the rotated position such that a multi-bar surface is formed. The multi-bar surface meets the bar-to-bar alignment and planarity specifications that allow either liquid resist or dry film resist to be used for photolithographic patterning.

A solderable pad patterning operation 1325 patterns a solderable pad onto a second surface of each of the microelectronic components of the mounted bars. To create the solderable pad, the solderable pad patterning operation 1325 deposits a layer of resist substantially evenly across the mounted bars. The resist is developed, such as by an exposure to high intensity light, and portions of the resist are removed such as by a developer solution. The solderable pad patterning operation 1325 forms a solderable pad on each of the microelectronic components by depositing several thin film layers substantially evenly across the surface of the mounted bars, including an adhesion layer, a diffusion barrier layer, and a surface oxidation layer.

The adhesion layer is deposited on top of and in contact with each of the microelectronic components of the mounted bars, and may function to prevent delamination of one or more upper thin film layers. In one implementation, the adhesion layer is titanium. The diffusion barrier layer is deposited on top of and in contact with the adhesion layer, and may function to protect the adhesion layer from reacting with one or more of the upper thin film layers. In one implementation, the diffusion barrier layer is nickel. The surface oxidation layer is deposited on top of and in contact with the diffusion barrier layer, and may insulate the diffusion barrier layer and provide a wetting surface for solder. The surface oxidation layer may be a metal that is not easily oxidized, such as gold.

In other implementations, other thin film layers are deposited in addition to or in lieu of the adhesion layer, the diffusion barrier layer, and the surface oxidation layer.

After the solderable pad patterning operation 1325 patterns the solderable pads on each of the microelectronic components, a solder layer patterning operation 1330 patterns a thin film layer of solder on each of the solderable pads. This thin film layer of solder may be deposited using a standard deposition process (e.g., vacuum evaporation) while the same patterned resist (i.e., the developed resist) is in place on each of the microelectronic components. In another implementation, the thin film layer of solder is applied to the individual microelectronic components after the bars are diced to separate the microelectronic components.

After the solder layer patterning operation, the patterned resist may be removed by a standard photoresist solvent, such as a resist-strip that chemically alters the patterned resist. The mounted bars may be unmounted and further diced by a dicing operation 1335 to separate the individual microelectronic components from one another.

In another implementation, the solderable pad patterning operation 1325 and solder layer patterning operation 1330 are performed during the surface feature patterning operation 1305. In such case, additional surface features are thereafter patterned onto a second surface of the mounted bars (i.e., a surface different from the first surface patterned during the surface feature patterning operation 1305) after the mounting step 1325.

The example operations for fabricating solderable pads on a microelectronic component discussed with respect to FIG. 13 may be performed to create solderable pads on interfacing surfaces of each of two microelectronic components, such as a slider and a submount. A thin film layer of solder, which may be formed on either or each of two solderable pads, may be heated to create a joint between the microelectronic components after or during an alignment process.

It should be understood that operations referred to in the implementations disclosed herein may be performed in any order, adding and omitting as desired, unless explicitly claimed otherwise or a specific order is inherently necessitated by the claim language. The above specification, examples, and data provide a complete description of the structure and use of exemplary implementations of the invention. Since many implementations of the invention can be made without departing from the spirit and scope of the invention, the invention resides in the claims hereinafter appended. Furthermore, structural features of the different implementations may be combined in yet other implementations without departing from the recited claims.

What is claimed is:

1. A method comprising:
patterning features on a first surface of a first microelectronic component;
rotating the first microelectronic component;
patterning a solderable pad on another surface of the first microelectronic component; and
patterning a solder layer on the solderable pad.

2. The method of claim 1, wherein the first microelectronic component is a laser submount assembly.

3. The method of claim 1, further comprising:
aligning the first microelectronic component with a second microelectronic component; and
flowing the solder layer between the solderable pad on the first microelectronic component and a solderable pad on the second microelectronic component.

4. The method of claim 3, wherein the first and second microelectronic components are aligned with micron or submicron precision.

5. The method of claim 1, wherein the first microelectronic component is part of a semiconductor wafer and the method further comprises:
slicing the semiconductor wafer into bars.

6. The method of claim 5, wherein rotating the first microelectronic component comprises rotating the bars, and the method further comprises:
mounting the bars to create a multi-bar surface that meets bar-to-bar alignment and planarity specifications operable to allow at least one of liquid resist or dry film resist to be used for photolithographic patterning.

7. The method of claim 1, wherein rotating the first microelectronic component comprises rotating the first microelectronic component by ninety degrees.

8. The method of claim 1, wherein rotating the first microelectronic component comprises rotating the first microelectronic component by 180 degrees.

9. The method of claim 1, wherein patterning the solderable pad comprises:
depositing an adhesion layer on the first microelectronic component;
depositing a diffusion barrier layer on the adhesion layer; and
depositing a surface oxidation layer on the diffusion barrier.

10. A method of making an apparatus, comprising:
patterning surface features on a first surface of a laser submount assembly;
patterning an under bump metallization (UBM) pad on a second surface of the laser submount assembly;
patterning surface features on a first surface of a slider;
patterning an under bump metallization (UBM) pad on a second surface of the slider;
providing a thin film layer of solder between the UBM pad of the slider and the UBM pad of the laser submount assembly; and
aligning the slider and the laser submount assembly with micron precision.

11. The method of claim 10, wherein aligning the slider and the laser submount assembly comprises aligning the slider and the laser submount assembly with submicron precision.

12. The method of claim 10, wherein patterning the UBM pad on the second surface of the laser submount assembly comprises:
providing an adhesion layer on a first side of a diffusion barrier layer; and
providing a surface oxidation layer on a second side of the diffusion barrier layer.

13. The method of claim 10, wherein patterning the UBM pad on the second surface of the slider comprises:
providing an adhesion layer on a first side of a diffusion barrier layer; and
providing a surface oxidation layer on a second side of the diffusion barrier layer.

14. The method of claim 10, wherein providing a thin film layer of solder comprises providing the thin film layer of solder on the UBM pad of the slider.

15. The method of claim 10, wherein providing a thin film layer of solder comprises providing the thin film layer of solder on the UBM pad of the laser submount assembly.

16. The method of claim 10, wherein patterning surface features on a first surface of a slider comprises patterning surface features of an advanced air-earing surface (AAB) on a first surface of a slider.
